(19) United States
(12) Patent Application Publication
(10) Pub. No.: US 2025/0280698 A1
(43) Pub. Date: Sep. 4, 2025

(54) Light Controlling Panel and Display Device Including the Same

(71) Applicant: LG Display Co., Ltd., Seoul (KR)

(72) Inventors: SangHyun Lee, Seongnam-si (KR); Dongll Yu, Seoul (KR)

(21) Appl. No.: 18/820,138

(22) Filed: Aug. 29, 2024

(30) Foreign Application Priority Data
Feb. 29, 2024 (KR) 10-2024-0029790

(51) Int. Cl. H10K 59/50; G02F 1/1343; G02F 1/167; G02F 1/1676; G02F 1/1677; G02F 1/1679; H10K 59/80

(52) U.S. Cl. CPC H10K 59/50; G02F 1/13439; G02F 1/167; G02F 1/1676; G02F 1/1677; G02F 1/1679; H10K 59/8792; G02F 2201/44

(57) ABSTRACT

A light controlling panel and a display device including the same are disclosed. The light controlling panel includes a first electrode, a second electrode on the first electrode to face the first electrode, a dielectric layer including a plurality of dielectric patterns that are provided between the first electrode and the second electrode and disposed between a plurality of grooves, and a plurality of spacers that protrude toward the second electrode from a portion of the plurality of dielectric patterns, and an ink layer disposed in a space between the dielectric layer and the second electrode and including charged particles, in which side surfaces of the plurality of dielectric patterns have a step shape. As a result, by reducing surface reflection on the side surfaces of the plurality of dielectric patterns, it is possible to improve the problem of deterioration in image quality such as phase separation or image reflection.

### CROSS-REFERENCE TO RELATED APPLICATION

This application claims the priority of Republic of Korea Patent Application No. 10-2024-0029790 filed on Feb. 29, 2024, in the Korean Intellectual Property Office, which is hereby incorporated by reference in its entirety.

### BACKGROUND

### Field

The present disclosure relates to a light controlling panel and a display device including the same, and more particularly, to a light controlling panel capable of improving image quality characteristics and a display device including the same.

### Description of the Related Art

As the society enters a full-scale information age, the field of display devices that visually display electrical information signals is developing rapidly. Accordingly, researchers are continuing to develop performance such as thinness, weight reduction, and lower power consumption for various display devices.

Representative display devices may include a liquid crystal display (LCD), a field emission display (FED), an electro-wetting display (EWD), and an organic light emitting display (OLED), etc.

An electroluminescent display, which is represented by the organic light emitting display, is a self-luminous display, and unlike the liquid crystal display, the electroluminescent display does not require a separate light source and may be manufactured in a lightweight and thin form. In addition, the electroluminescent display is not only advantageous in terms of power consumption due to low voltage operation, but also have excellent color reproduction, response speed, viewing angle, and contrast ratio (CR), so the electroluminescent display is expected to be utilized in various fields.

### SUMMARY

An object to be achieved by the present disclosure is to provide a light controlling panel capable of freely switching between light blocking mode and transmission mode according to user needs, and a display device including the same.

Another object to be achieved by the present disclosure is to provide a light controlling panel capable of improving image quality characteristics of a display device, and a display device including the same.

Still another object to be achieved by the present disclosure is to provide a light controlling panel with improved light transmittance in a transmissive mode of a display device, and a display device including the same.

Objects of the present disclosure are not limited to the above-mentioned objects, and other objects, which are not mentioned above, can be clearly understood by those skilled in the art from the following descriptions.

A light controlling panel according to an exemplary embodiment of the present disclosure includes a first electrode, a second electrode disposed on the first electrode to face the first electrode, a dielectric layer including a plurality of dielectric patterns that are provided between the first electrode and the second electrode and disposed between a plurality of grooves, and a plurality of spacers that protrude toward the second electrode from a portion of the plurality of dielectric patterns, and an ink layer disposed in a space between the dielectric layer and the second electrode and containing charged particles, in which side surfaces of the plurality of dielectric patterns have a step shape.

A display device according to another exemplary embodiment of the present disclosure includes a transparent display panel including a transmissive area through which external light transmits and a non-transmissive area where a plurality of pixels are disposed, and a light controlling panel disposed below the display panel, in which the light controlling panel includes a first electrode, a second electrode disposed on the first electrode to face the first electrode, a dielectric layer including a plurality of dielectric patterns that are provided between the first electrode and the second electrode and disposed between a plurality of grooves, and a plurality of spacers that protrude toward the second electrode from a portion of the plurality of dielectric patterns, and an ink layer disposed in a space between the dielectric layer and the second electrode and containing charged particles, and side surfaces of the plurality of dielectric patterns have a step shape.

Other detailed matters of the exemplary embodiments are included in the detailed description and the drawings.

In the light controlling panel and the display device including the same according to the exemplary embodiment of the present disclosure, it is possible to selectively implement the light blocking mode and the transmissive mode.

In the light controlling panel and the display device including the same according to the exemplary embodiment of the present disclosure, it is possible for the user to clearly view the objects and backgrounds located on the back surface of the display device in the transmissive mode and provide the user with the images with high contrast ratio by blocking the external light from penetrating into the display device in the light blocking mode.

In addition, in the light controlling panel and the display device including the same according to the exemplary embodiment of the present disclosure, by simultaneously forming the plurality of dielectric patterns, the plurality of spacers, and the plurality of grooves through the imprinting process, it is possible to reduce the manufacturing process costs, simplify the manufacturing process to shorten the manufacturing process time, and furthermore, reduce the production energy.

In addition, in the light controlling panel and the display device including the same according to the exemplary embodiment of the present disclosure, by optimizing the manufacturing process to reduce the generation of greenhouse gases that may be generated by the manufacturing process, it is possible to implement the environment/social/governance (ESG).

In addition, in the light controlling panel and the display device of according to the exemplary embodiment of the present disclosure, by forming the side surfaces of the plurality of dielectric patterns in the step shape to reduce the surface reflection from the side surfaces of the plurality of dielectric patterns, it is possible to improve the problem of deterioration in image quality such as the phase separation or image reflection.

In addition, in the light controlling panel and the display device according to another exemplary embodiment of the present disclosure, by forming the side surfaces of the plurality of dielectric patterns having the step shape in the unevenness shape to further reduce the surface reflection from the side surfaces of the plurality of dielectric patterns, it is possible to improve the problem of deterioration in image quality such as the phase separation or image reflection.

In addition, in the light controlling panel and the display device according to still another exemplary embodiment of the present disclosure, by including the plurality of pattern electrodes in the first electrode, it is possible to improve the light transmittance in the transmissive mode of the display device.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view of a display device according to an exemplary embodiment of the present disclosure;

FIG. 2 is a plan view of a display panel according to an exemplary embodiment of the present disclosure;

FIG. 3 is a schematic plan view of a plurality of pixels according to an exemplary embodiment of the present disclosure;

FIG. 4 is a circuit diagram of a sub-pixel of FIG. 3 according to an exemplary embodiment of the present disclosure;

FIG. 5 is a cross-sectional view taken along line V-V′ of FIG. 3 according to an exemplary embodiment of the present disclosure;

FIG. 6A is a perspective view of the display device according to the exemplary embodiment of the present disclosure;

FIG. 6B is a cross-sectional view in a light blocking mode taken along line B-B′ in FIG. 6A according to an exemplary embodiment of the present disclosure;

FIG. 6C is a cross-sectional view in the transmissive mode taken along line A-A′ of FIG. 6A according to an exemplary embodiment of the present disclosure;

FIG. 6D is a cross-sectional view in the transmissive mode taken along line B-B′ of FIG. 6A according to an exemplary embodiment of the present disclosure;

FIG. 7 is a cross-sectional view illustrating a light controlling panel according to another exemplary embodiment of the present disclosure;

FIG. 8A is a perspective view of a display device according to still another exemplary embodiment of the present disclosure;

FIG. 8B is a plan view illustrating a first electrode according to still another exemplary embodiment of the present disclosure;

FIG. 8C is a cross-sectional view in a transmissive mode taken along line C-C′ of FIG. 8A according to an exemplary embodiment of the present disclosure;

FIG. 8D is a cross-sectional view in the transmissive mode taken along line D-D′ of FIG. 8A according to an exemplary embodiment of the present disclosure;

FIGS. 9A to 9C are front of screen (FOS) images illustrating an appearance state of the display device in the transmissive mode from a front surface (90°), a first side surface (85°), and a second side surface (80°) according to Comparative Embodiment;

FIGS. 10A to 10C are the front of screen (FOS) images illustrating the appearance state of the display device in the transmissive mode from the front surface (90°), the first side surface (85°), and the second side surface (80°) according to Embodiment 1-1;

FIGS. 11A to 11C are the front of screen (FOS) images illustrating the appearance state of the display device in the transmissive mode from the front surface (90°), the first side surface (85°), and the second side surface (80°) according to Embodiment 1-2;

FIGS. 12A to 12C are the front of screen (FOS) images illustrating the appearance state of the display device in the transmissive mode from the front surface (90°), the first side surface (85°), and the second side surface (80°) according to Embodiment 2-1;

FIGS. 13A to 13C are the front of screen (FOS) images illustrating the appearance state of the display device in the transmissive mode from the front surface (90°), the first side surface (85°), and the second side surface (80°) according to Embodiment 2-2;

FIGS. 14A to 14C are graphs showing irradiance depending on a distance based on the front surface (90°), the first side surface (85°), and the second side surface (80°) according to Comparative Embodiment, Embodiment 1-1, and Embodiment 1-2, respectively; and

FIGS. 15A to 15C are graphs showing irradiance depending on a distance based on the front surface (90°), the first side surface (85°), and the second side surface (80°) according to Comparative Embodiment, Embodiment 2-1, and Embodiment 2-2, respectively.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

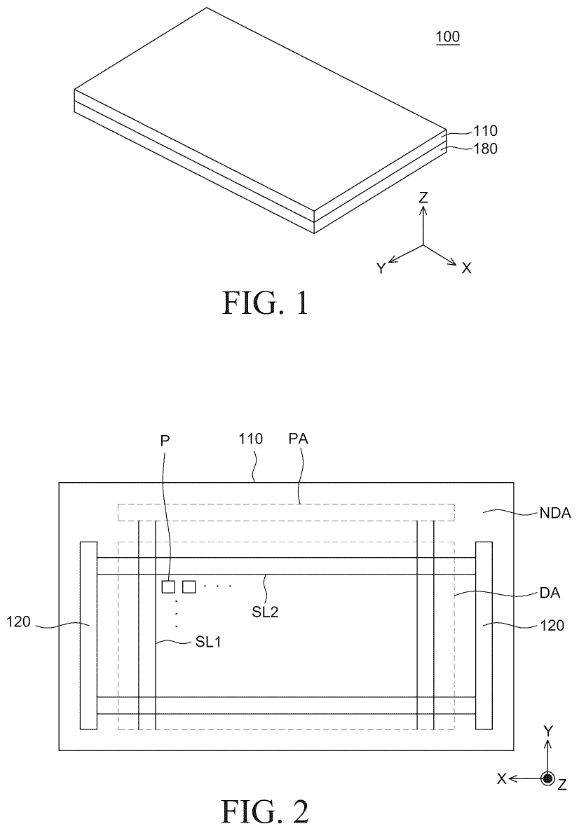

FIG. 1 is a perspective view of a display device according to an exemplary embodiment of the present disclosure.

In FIGS. 1 and 2, an X-axis represents a direction parallel to a gate line, a Y-axis represents a direction parallel to a data line, and a Z-axis represents a height direction of a display device.

A display device 100 according to an exemplary embodiment of the present disclosure will be described with a focus on being implemented as an organic light emitting display, but may also be implemented as a liquid crystal display or a plasma display panel (PDP), a quantum dot light emitting display (QLED), or an electrophoresis display.

Referring to FIG. 1, the display device 100 according to the exemplary embodiment of the present disclosure includes a display panel 110 and a light controlling panel 180.

The display device 100 according to the exemplary embodiment of the present disclosure may be the display device 100 in which at least a portion of a screen of the display device 100 that a viewer sees is transparent. For example, the display device 100 may be referred to as a transparent display device. The display device 100 according to the exemplary embodiment of the present disclosure may be the display device 100 that has at least transparency that enables a user to recognize objects on a back surface of the display device 100.

The display panel 110 is provided with a plurality of pixels P to display an image. At least some areas of the display panel 110 may be provided with a transmissive area that allows most of light incident from the outside to transmit. The display panel 110 may have the transmissive area between a plurality of pixels. The display panel 110 allows external objects or backgrounds to be visible due to the transmissive areas.

The light controlling panel 180 may be disposed on at least one surface of the display panel 110 and may control light incident on the display panel 110. The light controlling panel 180 may include an ink layer containing charged particle that move by an electric field. The light controlling panel 180 may implement a light blocking mode and a transmissive mode by controlling the movement of the ink layer containing the charged particle. Depending on a voltage applied to the ink layer containing the charged particle, the light blocking mode may be converted into the transmissive mode or the transmissive mode may be converted into the light blocking mode. The light controlling panel 180 may block incident light in the light blocking mode and transmit incident light in the transmissive mode.

In one embodiment, the light controlling panel 180 is disposed in a direction opposite to a direction in which the display panel 110 emits light. For example, when the display panel 110 is a top emission type, the light controlling panel 180 may be disposed below the display panel 110 as illustrated in FIG. 1. As another example, when the display panel 110 is a bottom emission type, the light controlling panel 180 may be disposed on the display panel 110.

Although not illustrated, the light controlling panel 180 may be attached to one surface of the display panel 110 using an adhesive layer. The adhesive layer (not illustrated) may be a transparent adhesive film such as optically clear adhesive (OCA) or a transparent adhesive such as optically clear resin (OCR).

In FIG. 1, the light controlling panel 180 is illustrated as being disposed on one surface exposed to the outside of the display panel 110, but is not necessarily limited thereto. The light controlling panel 180 may be disposed within the display panel 110. In this case, the light controlling panel 180 may be disposed on a top surface of one of a plurality of layers provided in the display panel 110. As an example, the light controlling panel 180 may be provided between a substrate and a transistor of the display panel 110. In this case, the light controlling panel 180 may not be provided with a separate substrate.

Hereinafter, the display panel 110 will be described in more detail with reference to FIGS. 2 to 5.

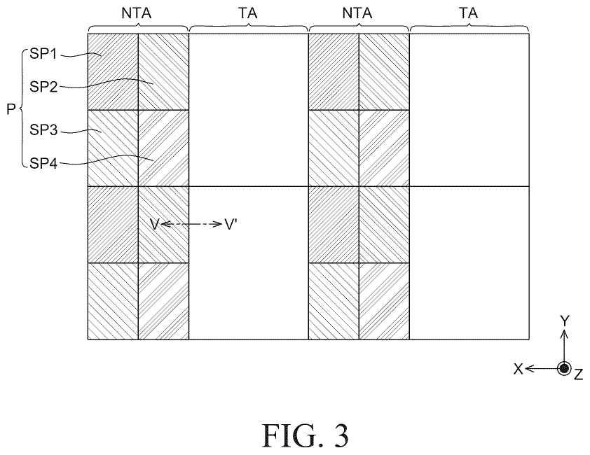

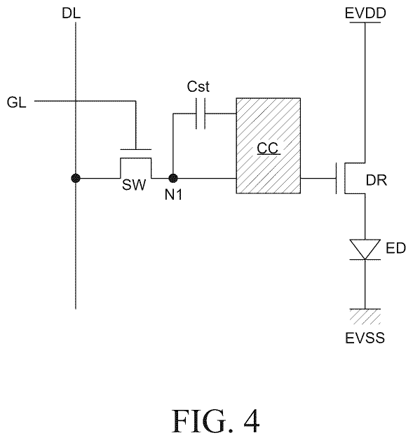

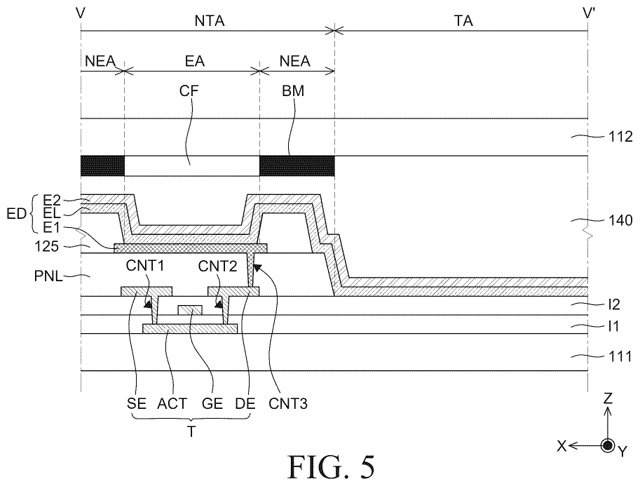

FIG. 2 is a plan view of a display panel according to an exemplary embodiment of the present disclosure. FIG. 3 is a schematic plan view of a plurality of pixels according to an exemplary embodiment of the present disclosure. FIG. 4 is a circuit diagram of a sub-pixel of FIG. 3 according to an exemplary embodiment of the present disclosure. FIG. 5 is a cross-sectional view taken along line V-V′ of FIG. 3 according to an exemplary embodiment of the present disclosure.

In FIG. 2, an X-axis represents a direction parallel to a gate line, a Y-axis represents a direction parallel to a data line, and a Z-axis represents a height direction of a display device.

Referring to FIGS. 2 to 5, the display panel 110 according to the exemplary embodiment of the present disclosure may be divided into a display area DA in which pixels P are formed to display images, and a non-display area NDA in which images are not displayed.

The display area DA may be provided with first signal lines SL1, second signal lines SL2, and pixels. The non-display area NDA may include a pad area PA where pads are disposed and at least one scan driver 120.

The first signal lines SL1 and the pixels P may be disposed to extend in one direction (e.g., Y-axis direction) in the display area DA. For example, the first signal lines SL1 may be data lines, but are not necessarily limited thereto. The first signal lines SL1 may include at least one of a pixel power line, a common power line, and a reference line.

The second signal lines SL2 may extend in the other direction (e.g., X-axis direction) intersecting one direction in the display area DA, and may intersect the first signal lines SL1 in the display area DA. For example, the second signal lines SL2 may be scan lines, but are not necessarily limited thereto.

The scan driver 120 is connected to a scan line to supply scan signals. This scan driver 120 may be formed in the non-display area NDA outside one or both sides of the display area DA of the display panel 110 using a gate driver in panel (GIP) type or a tape automated bonding (TAB) type.

The display area DA includes a transmissive area TA and a non-transmissive area NTA, as illustrated in FIG. 3. The transmissive area TA is an area that transmits most of light incident from the outside, and the non-transmissive area NTA is an area that does not transmit most of light incident from the outside. For example, the transmissive area TA may be an area where light transmittance is greater than α%, and the non-transmissive area NTA may be an area where the light transmittance is less than β%. In this case, α is a value greater than β. The display device 100 may view objects or backgrounds located on the back surface of the display device 100 due to the transmissive areas TA of the display panel 110.

The non-transmissive area NTA includes an emission area EA in which a plurality of pixels P are provided and emit light. Each of the plurality of pixels P may include a first sub-pixel SP1, a second sub-pixel SP2, a third sub-pixel SP3, and a fourth sub-pixel SP4. The first sub-pixel SP1 may include a first emission area EA that emits first color light, and the second sub-pixel SP2 may include a second emission area EA that emits second color light. The third sub-pixel SP3 may include a third emission area EA that emits third color light, and the fourth sub-pixel SP4 may include a fourth emission area EA that emits fourth color light.

For example, the first to fourth emission areas EA may all emit light of different colors. For example, the first emission area EA may emit green light, and the second emission area EA may emit red light. The third emission area EA may emit blue light, and the fourth emission area EA may emit white light. However, the present disclosure is not limited thereto. In addition, a disposition order of each sub-pixel SP1, SP2, SP3, and SP4 may change in various ways.

Referring to FIG. 4, each of the first to fourth sub-pixels SP1, SP2, SP3, and SP4 may include a switching transistor SW, a driving transistor DR, a capacitor Cst, a compensation circuit CC, and an organic light emitting diode (OLED).

The switching transistor SW transmits a data signal supplied through a data line DL to a first node N1 in response to a scan signal supplied through a gate line GL. The capacitor Cst is electrically connected to the first node N1 to charge a voltage applied to the first node N1. The driving transistor DR may control the amount of driving current flowing in the organic light emitting diode (ED) in response to the voltage applied to the gate electrode.

A semiconductor layer of the switching transistor SW or/and the driving transistor DR may contain silicon such as a-Si, poly-Si, or low-temperature poly-Si, or may contain oxide such as indium-gallium-zinc-oxide (IGZO), but is not limited thereto.

The organic light emitting diode (ED) outputs light corresponding to a driving current. The organic light emitting diode (ED) may output light corresponding to any one of red, green, and blue. The organic light emitting diode (ED) may include an anode electrode, a light emitting layer formed on the anode electrode, and a cathode electrode supplying a common voltage. The light emitting layer may be implemented to emit light of the same color for each pixel, such as white light, or may be implemented to emit different colors for each pixel, such as red, green, or blue light.

The compensation circuit CC may be provided in a pixel to compensate for a threshold voltage, etc., of the driving transistor DR. The compensation circuit CC may be composed of one or more transistors. The compensation circuit CC may include one or more transistors and a capacitor, and may be configured in various ways depending on the compensation method. The pixel including the compensation circuit CC may have various structures such as 3T1C, 4T2C, 5T2C, 6T1C, 6T2C, 7T1C, and 7T2C.

Referring to FIG. 5, in the display device 100 according to an exemplary embodiment of the present disclosure, the display panel 110 includes a lower substrate 111 and an upper substrate 112 facing each other, and a transistor T and a light emitting element ED including a lower electrode E1, an organic layer EL, and upper electrode E2 may be provided between the lower substrate 111 and the upper substrate 112.

The transistor T may include an active layer ACT provided on the lower substrate 111, a first insulating film I1 provided on the active layer ACT, a gate electrode GE provided on the first insulating film I1, a second insulating film 12 provided on the gate electrode GE, and a source electrode SE and a drain electrode DE provided on the second insulating film I2 and connected to the active layer ACT through first and second contact holes CNT1 and CNT2. In FIG. 5, the transistor T is illustrated as being formed in a top gate manner but is not limited thereto, and may be formed in a bottom gate manner in which the gate electrode GE is disposed below the active layer ACT.

A planarization film PLN may be provided on the transistor T and planarize steps caused by the transistor T and the plurality of signal lines. The planarization film PLN is provided in the non-transmissive area NTA and may not be provided in at least a portion of the transmissive area TA. The planarization film PLN may impair transparency by causing refraction of light as the light is transmitted. Accordingly, the display panel 110 in the display device 100 according to the exemplary embodiment of the present disclosure may increase transparency by removing a portion of the planarization film PLN from the transmissive area TA.

Meanwhile, in FIG. 5, the first and second insulating films I1 and I2 provided below the planarization film PLN are illustrated as being provided not only in the non-transmissive area NTA but also in the transmissive area TA, but are not necessarily limited thereto. Although not illustrated, for example, some of the insulating films provided below the planarization film PLN may not be provided in at least a portion of the transmissive area TA to increase transparency. For example, the second insulating film I2 is provided in the non-transmissive area NTA and may not be provided in at least a portion of the transmissive area TA.

The light emitting element ED including a lower electrode E1, an organic layer EL, and an upper electrode E2 and a bank 125 may be provided above the planarization film PLN.

The lower electrode E1 is provided for each sub-pixel SP1, SP2, SP3, and SP4 on the planarization film PLN, and may not be provided in the transmissive area TA. The lower electrode E1 may be electrically connected to the transistor T. Specifically, the lower electrode E1 may be connected to one of the source electrode SE and the drain electrode DE of the transistor T through a third contact hole CNT3 penetrating through the planarization film PLN. The bank 125 is provided between adjacent lower electrodes E1, so adjacent lower electrodes E1 may be electrically insulated from each other.

The lower electrode E1 may be formed of metal materials with high reflectance such as a laminated structure of aluminum and titanium (Ti/Al/Ti), a laminated structure of aluminum and ITO (ITO/Al/ITO), an Ag alloy, a laminated structure (ITO/Ag alloy/ITO) of Ag alloy and ITO, a MoTi alloy, and a laminated structure (ITO/MoTi alloy/ITO) of MoTi alloy and ITO. The Ag alloy may be an alloy of silver (Ag), palladium (Pd), copper (Cu), etc. The MoTi alloy may be an alloy of molybdenum (Mo) and titanium (Ti). This lower electrode E1 may be referred to as an anode electrode.

The bank 125 may be provided on the planarization film PLN. In addition, the bank 125 may be formed to cover an edge of the lower electrode E1 and expose a portion of the lower electrode E1. Accordingly, the bank 125 may suppress the problem of decreasing luminous efficiency due to the concentration of current at an end of the lower electrode E1. The organic layer EL may be provided on the lower electrode E1. The organic layer EL may include a hole transporting layer, a light emitting layer, and an electron transporting layer. In this case, when a voltage is applied to the lower electrode E1 and the upper electrode E2, holes and electrons move to the light emitting layer through the hole transporting layer and electron transporting layer, respectively, and combine with each other in the light emitting layer to emit light. In an exemplary embodiment, the organic layer EL may be a common layer commonly formed in sub-pixels SP1, SP2, SP3, and SP4. In this case, the light emitting layer may be a white light emitting layer that emits white light. In another exemplary embodiment, the light emitting layer of the organic layer EL may not be formed in the transmissive area TA.

The upper electrode E2 may be provided on the organic layer EL and the bank 125. The upper electrode E2 may be formed of a transparent conductive material (TCO) such as ITO or IZO that may transmit light, or an alloy of magnesium (Mg), silver (Ag), or may be formed of a semi-transmissive conductive material such as magnesium (Mg), silver (Ag), or an alloy of magnesium (Mg) and silver (Ag). When the upper electrode E2 is formed of the semi-transmissive conductive material, light output efficiency may increase due to a micro cavity. The upper electrode E2 may be referred to as a cathode electrode.

An encapsulation film 140 may be provided on the light emitting elements ED. The encapsulation film 140 may be formed on the upper electrode E2 to cover the upper electrode E2. The encapsulation film 140 serves to suppress oxygen or moisture from penetrating into the organic layer EL and the upper electrode E2. To this end, the encapsulation film 140 may include at least one inorganic film and at least one organic film.

A color filter CF may be provided on one surface of the upper substrate 112 facing the lower substrate 111. The color filter CF may be patterned for each sub-pixel SP1, SP2, SP3, and SP4.

Specifically, the color filter CF may include a first color filter, a second color filter, a third color filter, and a fourth color filter. The first color filter may be disposed to correspond to the emission area EA of the first sub-pixel SP1. For example, the first color filter may be a green color filter that transmits green light. The second color filter may be disposed to correspond to the emission area EA of the second sub-pixel SP2 and may be a red color filter that transmits red light. The third color filter CF3 may be disposed to correspond to the emission area EA of the third sub-pixel SP3 and may be a blue color filter that transmits blue light. The fourth color filter may be disposed to correspond to an emission area EA of the fourth sub-pixel SP4 and may be a white color filter that transmits white light. The white color filter may be formed of a transparent organic material that transmits white light, but is not necessarily limited thereto.

A black matrix BM may be provided between the color filters CF. The black matrix BM may be provided between the sub-pixels SP1, SP2, SP3, and SP4 to suppress color mixing from occurring between adjacent sub-pixels SP1, SP2, SP3, and SP4. In addition, the black matrix BM may suppress light incident from the outside from being reflected on a plurality of signal lines provided between the sub-pixels SP1, SP2, SP3, and SP4.

In addition, the black matrix BM may be provided between the transmissive area TA and the plurality of sub-pixels SP1, SP2, SP3, and SP4 to suppress the light emitted from each of the plurality of sub-pixels SP1, SP2, SP3, and SP4 from being transmitted to the transmissive area TA. In an exemplary embodiment, the black matrix BM may not be provided between a white sub-pixel and the transmissive area TA. In the display device 100 according to the exemplary embodiment of the present disclosure, the display panel 110 does not include the black matrix BM between the white sub-pixel and the transmissive area TA, thereby reducing the area where the black matrix BM is formed. As a result, in the display device 100 according to the exemplary embodiment of the present disclosure, the display panel 110 may improve transmittance. This black matrix BM may include a material that absorbs light, for example, black dye that absorbs all light in a visible light wavelength range.

The above-described color filter CF and black matrix BM are not provided in the transmissive area TA in order to maintain high light transmittance in the transmissive area TA.

The lower substrate 111 may be a plastic film, a glass substrate, or a silicon wafer substrate formed using a semiconductor process. The upper substrate 112 may be a plastic film, a glass substrate, or an encapsulation film. The upper substrate 111 and the lower substrate 112 may be formed of a transparent material. The lower substrate 111 may be formed to be larger than the upper substrate 112, so a portion of the lower substrate 111 may be exposed without being covered by the upper substrate 112.

As discussed above, the display device 100 according to the exemplary embodiment of the present disclosure includes the transmissive area TA, which almost transmits incident light as it is, and the emission area EA, which emits light. As a result, in the display device according to the exemplary embodiment of the present disclosure, objects or backgrounds located on the back surface or front surface of the display device 100 may be viewed through the transmissive area TA of the display device 100.

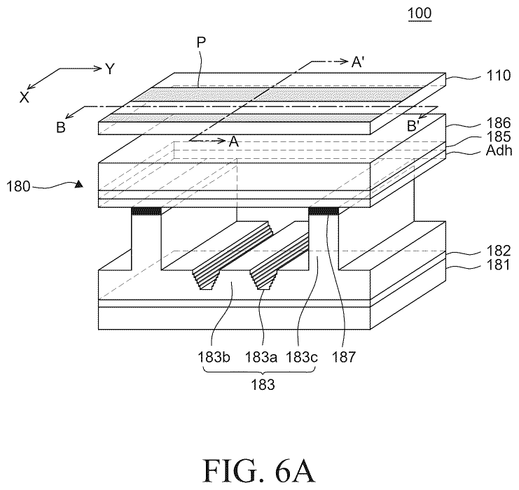

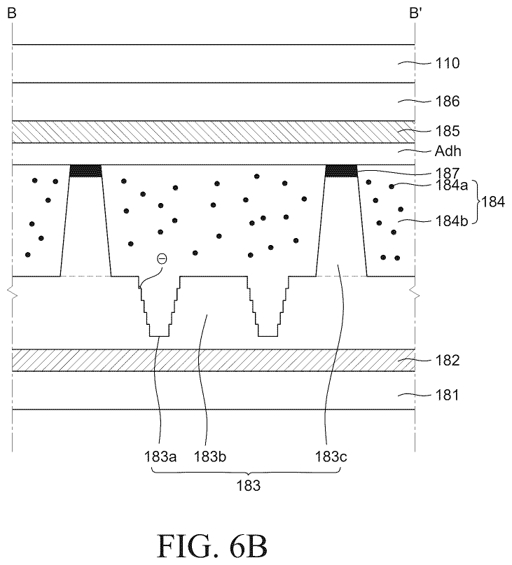

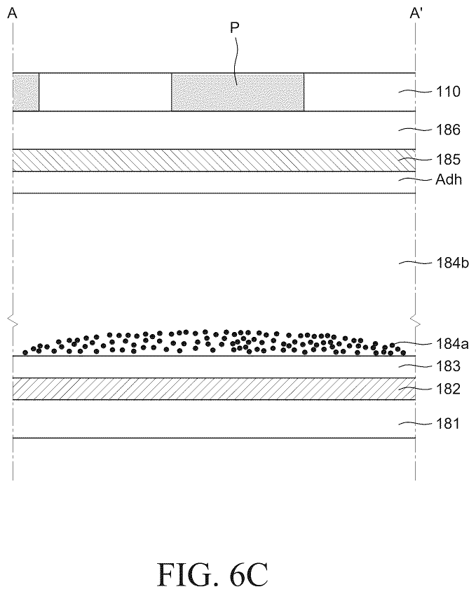

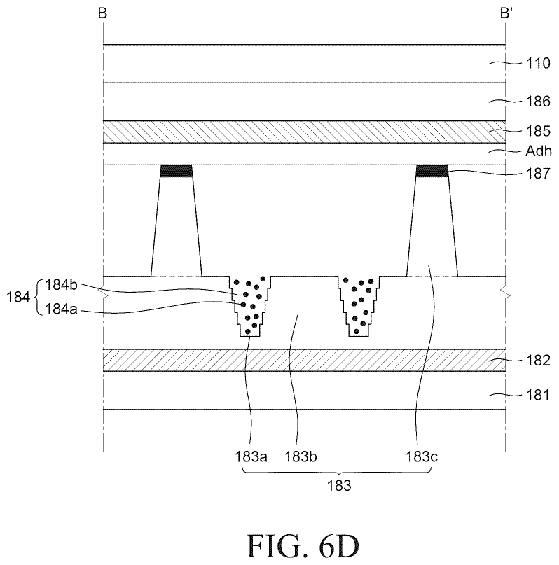

Hereinafter, the display device 100 will be described in more detail with reference to FIGS. 6A to 6D.

FIG. 6A is a perspective view of the display device according to the exemplary embodiment of the present disclosure. FIG. 6B is a cross-sectional view in a light blocking mode taken along line B-B′ in FIG. 6A according to an exemplary embodiment of the present disclosure. FIG. 6C is a cross-sectional view in the transmissive mode taken along line A-A′ of FIG. 6A according to an exemplary embodiment of the present disclosure. FIG. 6D is a cross-sectional view in the transmissive mode taken along line B-B′ of FIG. 6A according to an exemplary embodiment of the present disclosure. In FIG. 6A, the ink layer is omitted for convenience of illustration.

Referring to FIGS. 1 and 6A, in the display device 100 according to the exemplary embodiment of the present disclosure, the light controlling panel 180 may be implemented in a transmissive mode that transmits incident light and a light blocking mode that blocks incident light. In the display device 100 according to the exemplary embodiment of the present disclosure, it may be assumed that the light blocking mode indicates a case where the light transmittance of the light controlling panel 180 is less than α%, and the transmissive mode indicates a case where the light transmittance of the light controlling panel 180 is β% or more. In this case, α may represent a value smaller than β. The light transmittance of the light controlling panel 180 indicates a ratio of output light to light incident on the light controlling panel 180.

To this end, in the display device 100 according to the exemplary embodiment of the present disclosure, as illustrated in FIGS. 6A and 6B, the light controlling panel 180 includes a first substrate 181, a first electrode 182, and a dielectric layer 183, an ink layer 184, an adhesive layer Adh, a second electrode 185, and second substrate 186.

The first substrate 181 and second substrate 186 may each be a glass substrate or a plastic film, but is not limited thereto.

A first electrode 182 may be disposed on the first substrate 181.

The second electrode 185 may be disposed on one surface of the second substrate 186 facing the first substrate 181.

The first electrode 182 and the second electrode 185 may each be formed of a transparent conductive material. For example, the first electrode 182 and the second electrode 185 may be formed of a transparent conductive material such as tin oxide (TO), indium tin oxide (ITO), indium zinc oxide (IZO), and indium tin zinc oxide (ITZO), but is not limited thereto.

A dielectric layer 183 may be disposed between the first electrode 182 and the second electrode 185. The dielectric layer 183 may be formed of a transparent material and may transmit light, but is not limited thereto. For example, the dielectric layer 183 may be formed of a transparent resin. The transparent resin may be an acrylic-based resin, but is not limited thereto.

The dielectric layer 183 includes a plurality of grooves 183a, a plurality of dielectric patterns 183b, and a plurality of spacers 183c.

The plurality of grooves 183a may extend in a first direction and may be formed to be spaced at regular intervals in a second direction intersecting the first direction. For example, the plurality of grooves 183a are formed in a direction perpendicular to the disposition direction of the pixels P on the display panel 110 disposed over the light controlling panel 180. Therefore, the plurality of grooves 183a may be disposed to overlap both the non-transmissive area NTA and the transmissive area TA.

A plurality of dielectric patterns 183b are disposed between the plurality of grooves 183a. The plurality of dielectric patterns 183b may be formed in the same direction as the extension direction of the plurality of grooves 183a and may thus be disposed to overlap both the non-transmissive area NTA and the transmissive area TA.

In the display device 100 according to the exemplary embodiment of the present disclosure, side surfaces of the plurality of dielectric patterns 183b may have a step shape. Accordingly, the side surfaces of the plurality of grooves 183a in contact with the side surfaces of the plurality of dielectric patterns 183b may also have the step shape.

By forming the side surfaces of the plurality of dielectric patterns 183b in the step shape, it is possible to suppress surface reflection of light incident on the side surface. Specifically, even if light is incident on the side surfaces of the plurality of dielectric patterns 183b, a light path may change due to the step shape of the plurality of dielectric patterns 183b and may be incident into the plurality of grooves 183a. Accordingly, the surface reflection of light incident on the side surfaces of the plurality of dielectric patterns 183b may be suppressed, thereby improving the problem of image quality such as image reflection or phase separation such as double image.

In this case, the number of step shapes formed on the side surfaces of the plurality of dielectric patterns 183b may be five or more, but is not limited thereto, and the number of step shapes may vary depending on the height of the plurality of dielectric patterns 183b. Additionally, an angle θ forming each step-shaped layer may be 90°, but is not limited thereto, and the angle θ may vary as needed.

A plurality of spacers 183c protruding toward the second electrode 185 are disposed on a portion of the plurality of dielectric patterns 183b. For example, the plurality of spacers 183c may be formed in the same direction as the extension direction of the plurality of grooves 183a and the plurality of dielectric patterns 183b and may thus be disposed to overlap both the non-transmissive area NTA and the transmissive area TA.

In FIGS. 6A and 6B, for convenience of description, it is illustrated that the two spacers 183c of the dielectric layer 183 may be disposed on the two dielectric patterns 183b disposed on the outermost side, and the plurality of grooves 183a and one dielectric pattern 183b are disposed between the two spacers 183c but is not limited thereto, and the dielectric layer 183 may have two or more dielectric patterns 183b disposed between the two spacers 183c. In addition, the dielectric layer 183 may have the above-described structure continuously disposed. That is, the dielectric layer 183 may include the plurality of grooves 183a and the plurality of dielectric patterns 183b disposed between the two spacers 183c.

The plurality of spacers 183c may maintain a constant interval between the first substrate 181 and the second substrate 186. That is, the interval between the first substrate 181 and the second substrate 186 may be determined by the height of the plurality of spacers 183c.

The top surfaces of the plurality of dielectric patterns 183b and the plurality of spacers 183c may have a flat shape. For example, when the top surfaces of the plurality of dielectric patterns and the plurality of spacers are convex, total reflection may occur due to a difference in refractive index between the plurality of dielectric patterns and the plurality of spacers and the solvent of the ink layer, resulting in the phase separation. As in an exemplary embodiment of the present disclosure, when the top surfaces of the plurality of dielectric patterns 183b and the plurality of spacers 183c are flat, the total reflection may not occur at the top surfaces of the plurality of dielectric patterns 183b and the plurality of spacers 183c, so the image quality may be improved.

Each of the plurality of dielectric patterns 183b and the plurality of spacers 183c may have a trapezoidal shape with a bottom surface wider than the top surface. For example, each of the plurality of dielectric patterns 183b and the plurality of spacers 183c may have a trapezoidal shape in which the bottom surface in contact with the first electrode 182 is wider than the top surface in contact with the second electrode 185, but is not limited thereto, and each of the plurality of dielectric patterns 183b and the plurality of spacers 183c may have a squared, rectangular, or triangular cross-sectional shape.

Meanwhile, the plurality of dielectric patterns 183b and the plurality of spacers 183c may be formed integrally. That is, the plurality of dielectric patterns 183b and the plurality of spacers 183c included in the dielectric layer 183 may be formed integrally and formed of the same material. For example, the plurality of grooves 183a, the plurality of dielectric patterns 183b, and the plurality of spacers 183c may be formed simultaneously by the imprinting process. Accordingly, as the process is simplified, the process optimization may be possible by reducing the process costs and shortening the process time, and furthermore, the production energy may be reduced. In addition, since the process optimization of the display device 100 according to the exemplary embodiment of the present disclosure may reduce the generation of the greenhouse gases that may be generated by the manufacturing process, it is possible to implement the environment/social/governance (ESG).

The display device 100 according to the exemplary embodiment of the present disclosure may further include a light blocking pattern 187 disposed on the top surface of the plurality of spacers 183c. For example, the light blocking pattern 187 may be formed of a black-based material. For example, the light blocking pattern 187 may be coated on the top surfaces of the plurality of spacers 183c to suppress light from transmitting through the plurality of spacers 183c.

In the display device 100 according to the exemplary embodiment of the present disclosure, the light controlling panel 180 may include the ink layer 184 disposed in the space between the dielectric layer 183 and the second electrode 185. Specifically, the ink layer 184 may be disposed in the space between the plurality of grooves 183a and the plurality of dielectric patterns 183b and the second electrode 185, but is not limited thereto. For example, the ink layer 184 may not be disposed between the plurality of spacers 183c and the second electrode 185.

In the display device 100 according to the exemplary embodiment of the present disclosure, the ink layer 184 may include a plurality of charged particles 184a provided in the solvent 184b. Specifically, the plurality of charged particles 184a may be negatively or positively charged and distributed within the solvent 184b, and may block light incident from the outside. For example, the solvent 184b may be a transparent organic solvent. In addition, for example, the plurality of charged particles 184a may be an electrophoresis material, for example, may be formed of black ink containing carbon black, but is not limited thereto.

In the display device 100 according to the exemplary embodiment of the present disclosure, the adhesive layer Adh is disposed between the ink layer 184 and the plurality of spacers 183c and the second electrode 185. For example, the adhesive layer Adh may be a transparent adhesive film such as optically clear adhesive (OCA) or a transparent adhesive such as optically clear resin (OCR).

In the display device 100 according to the exemplary embodiment of the present disclosure, the light controlling panel 180 is disposed outside the display panel 110 as illustrated in FIGS. 1 and 6A, and may be provided in a separate configuration from the display panel 110. In this case, the light controlling panel 180 may be formed in a film form and disposed on one surface of the display panel 110 with a separate adhesive layer, but is not limited to thereto.

Although not illustrated, for example, the light controlling panel 180 may be disposed within the display panel 110. In this case, the light controlling panel 180 may be disposed between the lower substrate 111 and the upper substrate 112 of the display panel 110. In this case, the first substrate 181 and the second substrate 186 of the light controlling panel 180 may be omitted, but is not limited thereto.

Hereinafter, the method of implementing the transmissive mode and the light blocking mode depending on whether a voltage is applied will be described in detail with reference to the drawings.

As illustrated in FIG. 6B, when no voltage is applied to the first electrode 182 and the second electrode 185, the plurality of charged particles 184a are evenly distributed and disposed within the ink layer 184. Therefore, a light blocking mode in which light from the outside is blocked by the plurality of evenly disposed charged particles 184a may be implemented. The external light does not transmit the light controlling panel 180.

In addition, in the display device 100 according to the exemplary embodiment of the present disclosure, as the light blocking pattern 187 is disposed on the top surfaces of the plurality of spacers 183c of the light controlling panel 180, so that when implementing the light blocking mode, the blocking of light may be further improved.

Meanwhile, when a voltage is applied to the first electrode 182 and the second electrode 185, the dielectric polarization may occur in the dielectric material of the plurality of dielectric patterns 183b, and the dielectric polarization density may vary according to the shape of the top surface of the dielectric layer 183. Accordingly, the electric field may be formed strongest in the plurality of grooves 183a.

Since the plurality of charged particles 184a move by the electric field generated between the first electrode 182 and the second electrode 185, when a voltage is applied to the first electrode 182 and the second electrode 185, the plurality of charged particles 184a may move to the plurality of groove 183a along the electric field.

Looking at a cross-sectional view of a portion overlapping with the transmissive area TA of the display panel 110 in the transmissive mode in which the voltage is applied to the first electrode 182 and the second electrode 185, as illustrated in FIG. 6D, the plurality of charged particles 184a are located only within the plurality of grooves 183a, so the plurality of charged particles 184a may not be disposed in the area overlapping the plurality of dielectric patterns 183b and may have the high light transmittance. Accordingly, when a voltage is applied to the first electrode 182 and the second electrode 185, the external light may transmit the area where the plurality of dielectric patterns 183b and the plurality of spacers 183c are disposed, and the light transmitting the light controlling panel 180 may be incident on the display panel 110.

In addition, looking at the cross-sectional view of the portion overlapping the bottom surface of the plurality of grooves 183a in the transmissive mode in which the voltage is applied to the first electrode 182 and the second electrode 185, as illustrated in FIG. 6C, the plurality of charged particles 184a are located only within the plurality of grooves 183a in both the transmissive area TA where the pixel P of the display panel 110 is not disposed and the non-transmissive area NTA where the pixel P is disposed. Accordingly, the plurality of charged particles 184a may not be disposed in the area overlapping the plurality of dielectric patterns 183b and may have the high light transmittance. Accordingly, when a voltage is applied to the first electrode 182 and the second electrode 185, the external light may transmit the area where the plurality of dielectric patterns 183b and the plurality of spacers 183c are disposed, and the light transmitting through the light controlling panel 180 may be incident on the display panel 110.

In this way, the external light may transmit the display device 100 through the area where the plurality of dielectric patterns 183b of the light controlling panel 180 is formed and the transmissive area TA of the display panel 110. In order to have the high light transmittance in the transmissive mode, the display device 100 according to the exemplary embodiment of the present disclosure may have the plurality of dielectric patterns 183b of the light controlling panel 180 to overlap the transmissive area TA of the display panel 110.

In addition, according to the exemplary embodiment of the present disclosure, the side surfaces of the plurality of dielectric patterns 183b have the step shape, so even if light is incident on the side surfaces of the plurality of dielectric patterns 183b, light may be input to the plurality of grooves 183a by changing the optical path due to the step shape on the side surfaces of the plurality of dielectric patterns 183b. When a voltage is applied to the first electrode 182 and the second electrode 185, the plurality of charged particles 184a move to the plurality of grooves 183a along the electric field, and the external light incident into the plurality of grooves 183a may be absorbed by the plurality of charged particles 184a located inside the plurality of grooves 183a.

Conventionally, when the external light is applied to the light controlling panel, in particular, the light incident on the side surface is incident on the inclined side surfaces of the plurality of dielectric patterns, so there is a problem in which the surface reflection occurs due to the difference in refractive index between the plurality of dielectric patterns and the solvent of the link layer and the optical path changes. In this way, when the surface reflection occurs on the side surfaces of the plurality of dielectrics, the problem of deterioration in image quality such as the phase separation or the image reflection such as the double image occur.

Accordingly, in the display device 100 according to the exemplary embodiment of the present disclosure, the side surfaces of the plurality of dielectric patterns 183b have the step shape, so the light incident on the side surface is not reflected from the side surfaces of the plurality of dielectric patterns 183b and the optical path may change to be input into the plurality of grooves 183a. The light incident into the plurality of grooves 183a may be absorbed by the plurality of charged particles 184a located inside the plurality of grooves 183a, thereby improving the problem of image quality such as the phase separation or the image reflection.

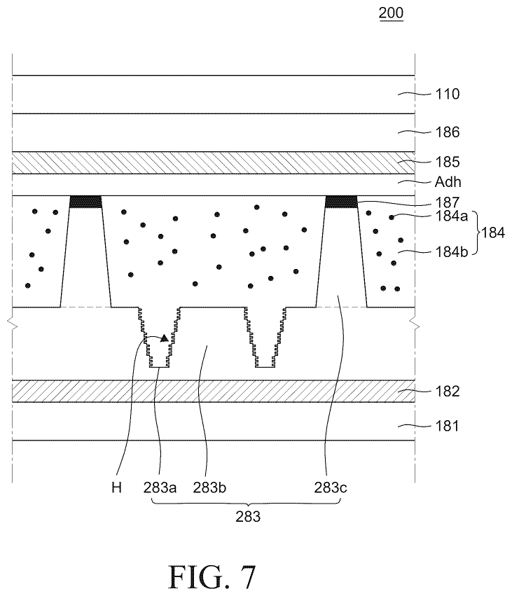

FIG. 7 is a cross-sectional view of a display device according to another embodiment of the present disclosure. The display device of FIG. 7 is different from the display device of FIGS. 1 to 6A-6D only in the dielectric layer 283, and other structures are substantially the same, and therefore, redundant description thereof will be omitted.

Referring to FIG. 7, in the light controlling panel according to another embodiment of the present disclosure, the dielectric layer 283 includes a plurality of grooves 283a, a plurality of dielectric patterns 283b, and a plurality of spacers 283c.

The plurality of grooves 283a may extend in a first direction and may be formed to be spaced at regular intervals in a second direction intersecting the first direction. For example, the plurality of grooves 283a are formed in a direction perpendicular to the disposition direction of the pixels P on the display panel 110 disposed over the light controlling panel, and may thus be disposed to overlap both the non-transmissive area NTA and the transmissive area TA.

A plurality of dielectric patterns 283b are disposed between the plurality of grooves 283a. The plurality of dielectric patterns 283b may be formed in the same direction as the extension direction of the plurality of grooves 283a and may thus be disposed to overlap both the non-transmissive area NTA and the transmissive area TA.

In this case, the side surfaces of the plurality of dielectric patterns 283b may have the step shape.

By forming the side surfaces of the plurality of dielectric patterns 283b in the step shape, it is possible to suppress surface reflection of light incident on the side surface. Specifically, even if light is incident on the side surfaces of the plurality of dielectric patterns 283b, a light path may change due to the step shape of the plurality of dielectric patterns 283b and may be incident into the plurality of grooves 283a. Accordingly, the surface reflection of light incident on the side surfaces of the plurality of dielectric patterns 283b may be suppressed, thereby improving the problem of image quality such as the image reflection or the phase separation such as the double image.

In addition, in the light controlling panel according to another exemplary embodiment of the present disclosure, the side surfaces of the plurality of dielectric patterns 283b having a plurality of step shapes may have an unevenness shape H such as haze or curved lines. Accordingly, the side surfaces of the plurality of grooves 283a in contact with the side surfaces of the plurality of dielectric patterns 283b may also have the step shape and the unevenness shape.

For example, when perforating the side surfaces of the plurality of dielectric patterns 283b having the step shape using a laser, the unevenness shape H, such as embossing, may be irregularly formed on the side surfaces of the plurality of dielectric patterns 283b having the step shape.

In addition, the plurality of spacers 283c protruding toward the second electrode 185 are disposed on a portion of the plurality of dielectric patterns 283b. In this case, as the plurality of spacers 283c are disposed on a portion of the plurality of dielectric patterns 283b, the side surfaces of the plurality of dielectric patterns 283b disposed below the plurality of spacers 283c may also irregularly formed with the unevenness shape H such as the embossing.

By forming the side surfaces of the plurality of dielectric patterns 283b in the step shape, it is possible to suppress the surface reflection of light incident on the side surfaces of the plurality of dielectric patterns 283b. Specifically, even if light is incident on the side surfaces of the plurality of dielectric patterns 283b, the light path may change due to the step shape of the side surfaces of the plurality of dielectric patterns 283b and may be incident into the plurality of grooves 283a. Accordingly, the surface reflection of light incident on the side surfaces of the plurality of dielectric patterns 283b may be suppressed, thereby improving the problem of image quality such as the image reflection or the phase separation such as the double image.

In addition, when the unevenness shape H is irregularly disposed on the side surfaces of the plurality of dielectric patterns 283b having the step shape, the light incident on the side surfaces of the plurality of dielectric patterns 283b may be scattered by the unevenness shape H. Accordingly, the light incident on the side surfaces of the plurality of dielectric patterns 283b may be scattered by the unevenness shape H and incident into the plurality of grooves 283a. Accordingly, the surface reflection of light incident on the side surfaces of the plurality of dielectric patterns 283b may be further suppressed, thereby further improving the problem of image quality such as the image reflection or the phase separation such as the double image.

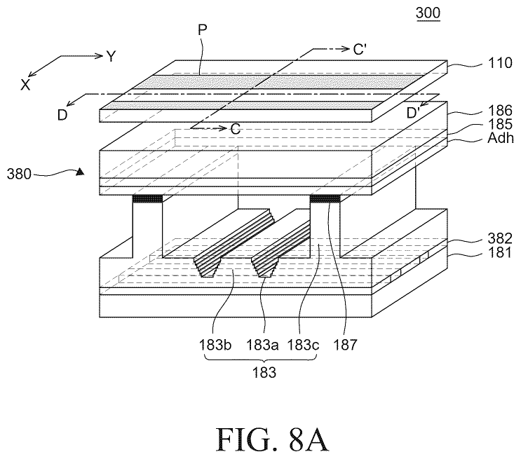

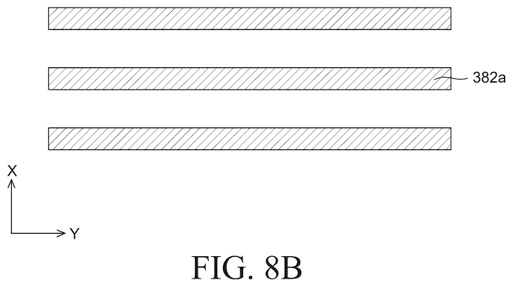

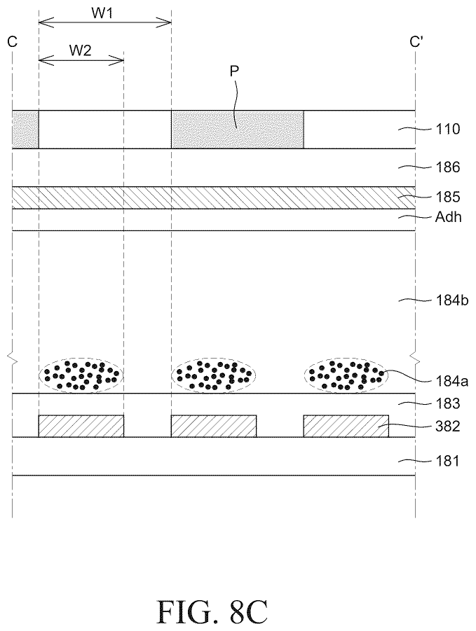

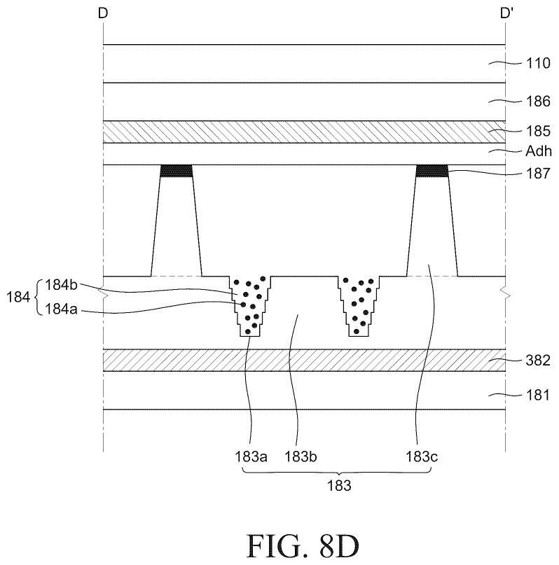

Hereinafter, a display device 300 according to still another exemplary embodiment of the present disclosure will be described in more detail with reference to FIGS. 8A to 8D.

FIG. 8A is a perspective view of a display device according to still another exemplary embodiment of the present disclosure. FIG. 8B is a plan view illustrating a first electrode according to still another exemplary embodiment of the present disclosure. FIG. 8C is a cross-sectional view in a transmissive mode taken along line C-C′ of FIG. 8A according to an exemplary embodiment of the present disclosure. FIG. 8D is a cross-sectional view in the transmissive mode taken along line D-D′ of FIG. 8A according to an exemplary embodiment of the present disclosure. The display device 300 of FIGS. 8A to 8D is different from the display device 100 of FIGS. 1 to 6A-6D only in the first electrode 382 and other components are substantially the same, and therefore, redundant descriptions thereof will be omitted.

Referring to FIGS. 8A and 8B, in the display device 300 according to the embodiment of the present disclosure, the first electrode 382 may include the plurality of patterned pattern electrodes 382a spaced apart from each other. In this case, the first electrode 382 may extend in the second direction and may be in the form of stripe spaced at regular intervals in the first direction intersecting the second direction. That is, the first electrode 382 may extend in a direction that intersects the extension direction of the plurality of grooves 183a, the plurality of dielectric patterns 183b, and the plurality of spacers 183c.

For example, the first electrode 382 may include two or more pattern electrodes 382a. For example, when the first electrode 382 includes two pattern electrodes 382a, the first electrode 382 may be located at both ends of the display device 300. Alternatively, when the first electrode 382 includes three or more pattern electrodes 382a, three or more pattern electrodes may be spaced apart at equal intervals over the entire area of the display device 300. For example, when the first electrode 382 is formed of two pattern electrodes 382a and is located at both ends of the display device 300, the transmittance may be further improved, but is not limited thereto.

Hereinafter, the method of implementing the transmissive mode according to the voltage application will be described in detail with reference to the drawings.

When a voltage is applied to the first electrode 382 and the second electrode 185, the dielectric polarization may occur in the dielectric material of the plurality of dielectric patterns 183b, and the dielectric polarization density may vary according to the shape of the top surface of the dielectric layer 183. Accordingly, the electric field may be formed strongest in the plurality of grooves 183a that overlap the first electrode 382.

Since the plurality of charged particles 184a move by the electric field generated between the first electrode 382 and the second electrode 185, when a voltage is applied to the first electrode 382 and the second electrode 185, the plurality of charged particles 184a may move to the plurality of grooves 183a to overlap the first electrode 382 along the electric field.

Looking at a cross-sectional view of a portion overlapping with the transmissive area TA of the display panel 110 in the transmissive mode in which a voltage is applied to the first electrode 382 and the second electrode 185, as illustrated in FIG. 8D, the plurality of charged particles 184a are located only within the plurality of grooves 183a, so the plurality of charged particles 184a may not be disposed in the area overlapping the plurality of dielectric patterns 183b and may have the high light transmittance. Accordingly, when a voltage is applied to the first electrode 382 and the second electrode 185, the transmission mode in which the external light may transmit the area where the plurality of dielectric patterns 183b and the plurality of spacers 183c are disposed may be implemented, so the light transmitting the light controlling panel 180 may be incident on the display panel 110.

Meanwhile, looking at the cross-sectional view of the portion overlapping the bottom surfaces of the plurality of grooves 183a in the transmissive mode in which a voltage is applied to the first electrode 382 and the second electrode 185, as illustrated in FIG. 8C, the plurality of charged particles 184a are collected in an island shape at an intersection where the plurality of grooves 183a and the stripe-shaped first electrode 382 overlap in the transmissive area TA where the pixel P of the display panel 110 is not disposed and the non-transmissive area NTA where the pixel P of the display panel 110 is disposed, so the light transmittance may be further improved.

That is, the plurality of charged particles 184a may not be distributed in the entire area of the plurality of grooves 183a, but may be distributed only in the area where the patterned first electrode 382 and the plurality of grooves 183a intersect. In this case, the external light may be blocked without transmitting the area where the plurality of grooves 183a are formed by the plurality of charged particles 184a.

The plurality of grooves 183a may extend in the first direction.

The groove 183a has a second width W2, and the second width W2 may be smaller than a first width W1 between adjacent pixels P in the display panel P, that is, the first width W1 of the transmissive area TA. For example, the first width W1 may be twice the second width W2, but is not limited thereto.

That is, in the light controlling panel 380 according to the exemplary embodiment of the present disclosure, the second width W2 of the plurality of grooves 183a is smaller than the first width W1 of the transmissive area TA of the display panel 110, so the transmissive area TA of the display panel 110 may have the area that does not overlap with the plurality of grooves 183a. Accordingly, it is possible to suppress the decrease in light transmittance of the display device 300 due to the plurality of charged particles 184a disposed in the plurality of grooves 183a in the transmissive mode.

In addition, in the transmissive mode, the light is transmitted through the upper portion of the plurality of dielectric patterns 183b where the plurality of charged particles 184a are not disposed, so the high light transmittance may be achieved.

In addition, the island-shaped charged particles 184a disposed in the plurality of grooves 183a in the transmissive area TA may not be visible to a user since the second width W2 of the plurality of grooves 183a is sufficiently small compared to the transmissive area TA.

Hereinafter, the effect according to the exemplary embodiment of the present disclosure described above will be described in more detail through various exemplary embodiments.

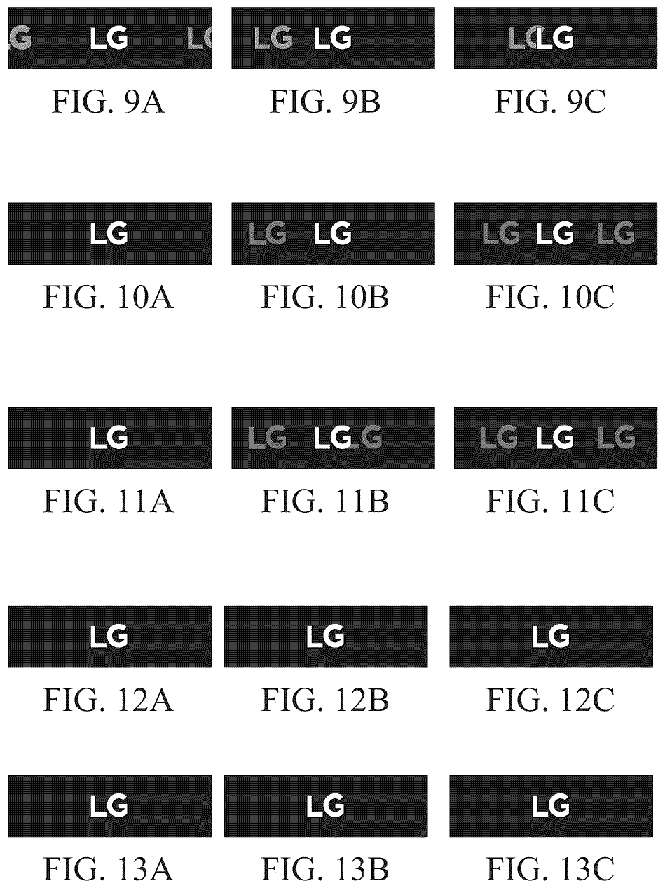

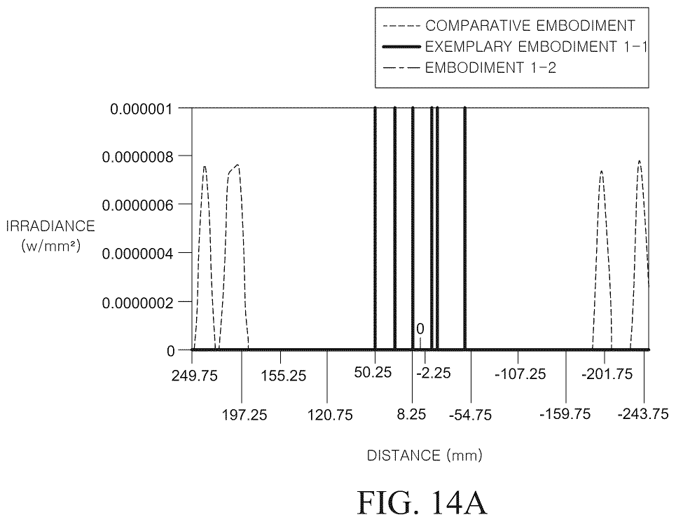

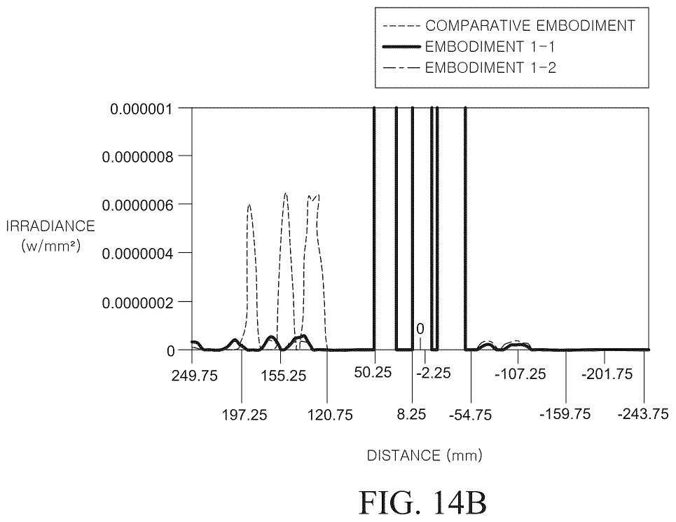

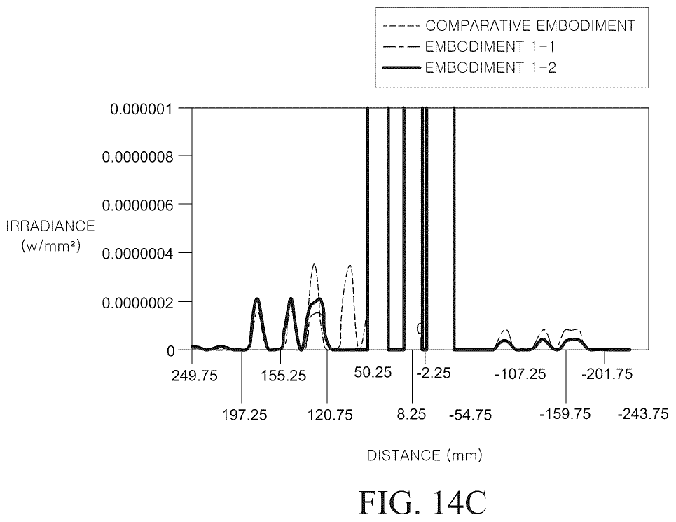

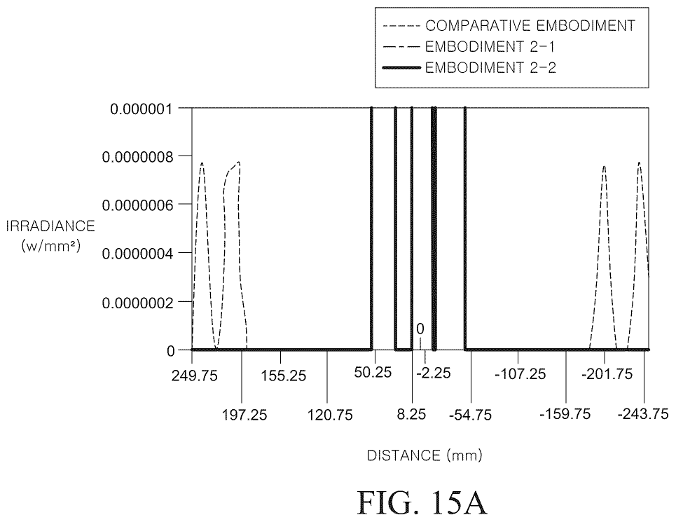

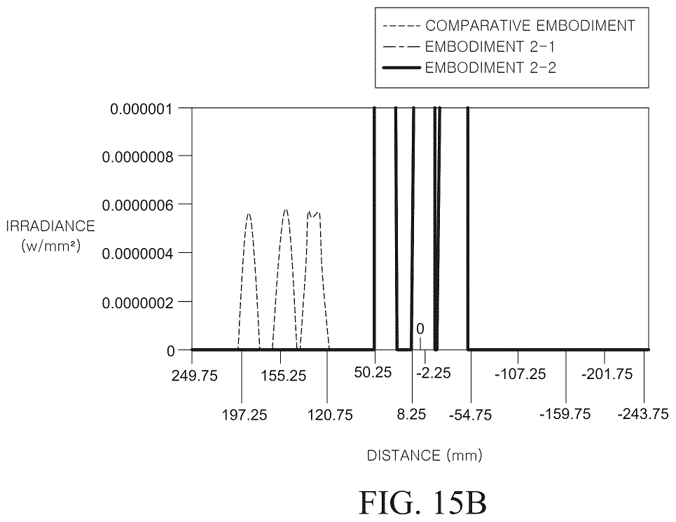

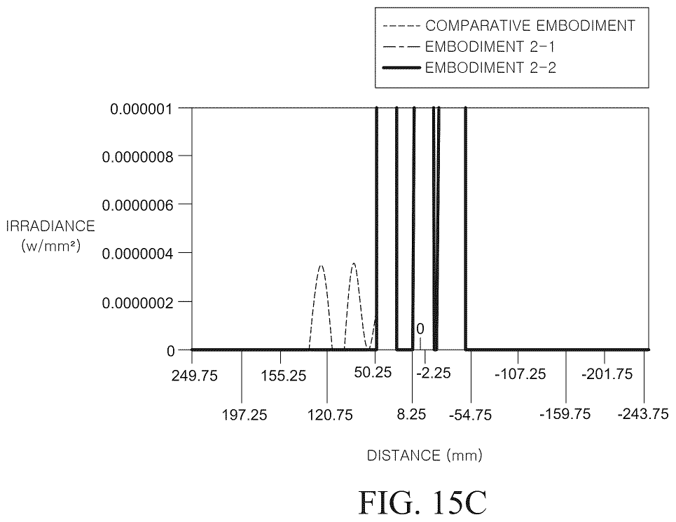

FIGS. 9A to 9C are front of screen (FOS) images illustrating an appearance state of the display device in the transmissive mode from a front surface (90°), a first side surface (85°), and a second side surface (80°) according to Comparative Embodiment. FIGS. 10A to 10C are the FOS images illustrating the appearance state of the display device in the transmissive mode from the front surface (90°), the first side surface (85°), and the second side surface (80°) according to Embodiment 1-1. FIGS. 11A to 11C are the FOS images illustrating the appearance state of the display device in the transmissive mode from the front surface (90°), the first side surface (85°), and the second side surface (80°) according to Embodiment 1-2. FIGS. 12A to 12C are the FOS images illustrating the appearance state of the display device in the transmissive mode from the front surface (90°), the first side surface (85°), and the second side surface (80°) according to Embodiment 2-1. FIGS. 13A to 13C are the FOS images illustrating the appearance state of the display device in the transmissive mode from the front surface (90°), the first side surface (85°), and the second side surface (80°) according to Embodiment 2-2. FIGS. 14A to 14C are graphs showing irradiance depending on a distance based on the front surface (90°), the first side surface (85°), and the second side surface (80°) according to Comparative Embodiment, Embodiment 1-1, and Embodiment 1-2, respectively. FIGS. 15A to 15C are graphs showing irradiance depending on a distance based on the front surface (90°), the first side surface (85°), and the second side surface (80°) according to Comparative Embodiment, Embodiment 2-1, and Embodiment 2-2, respectively.

The FOS is a qualitative indicator and may be defined as the degree of uniformity of the screen that a viewer feels when watching the video on the screen of the display device.

First, Embodiment 1-1 of FIGS. 10A to 10C is the display device 100 according to an exemplary embodiment of the present disclosure. In this case, in Embodiment 1-1, the number of step shapes formed on the side surfaces of the plurality of dielectric patterns 183b is 5.

In addition, Embodiment 1-2 of FIGS. 11A to 11C is the display device 100 according to an exemplary embodiment of the present disclosure. In this case, in Embodiment 1-2, the number of step shapes formed on the side surfaces of the plurality of dielectric patterns 183b is 10.

In addition, Embodiment 2-1 of FIGS. 12A to 12C is the display device 200 according to another exemplary embodiment of the present disclosure. In this case, Embodiment 2-1 has a structure in which the unevenness shape H is disposed on the side surfaces of the plurality of dielectric patterns 283b having the step shape, and the number of step shapes formed on the side surfaces of the plurality of dielectric patterns 283b is 5.

In addition, Embodiment 2-2 of FIGS. 13A to 13C is the display device 200 according to another exemplary embodiment of the present disclosure. In this case, Embodiment 2-2 has a structure in which the unevenness shape H is disposed on the side surfaces of the plurality of dielectric patterns 283b having the step shape, and the number of step shapes formed on the side surfaces of the plurality of dielectric patterns 283b is 10.

Meanwhile, Comparative Embodiments of FIGS. 9A to 9C has a structure in which the side surfaces of the plurality of dielectric patterns are inclined compared to Embodiment 1-1.

To confirm the phase separation in the transmissive mode, the front of screen (FOS) image is taken from the display device with “LG” written in the center.

Looking at the FOS image of the front surface (90°), the first side surface (85°), and the second side surface (80°) of Comparative Embodiment, Embodiment 1-1, and Embodiment 1-2 with reference to the drawings, in the case of Comparative Embodiment, it was confirmed that the phase separation occurred on both the front side surface (90°) as illustrated in FIG. 9A, the first side surface (85°) as illustrated in FIG. 9B, and the second side surface (80°) as illustrated in FIG. 9C.

In Embodiments 1-1 and 1-2, almost no phase separation occurred at the front surface (90°) as illustrated in FIGS. 10A and 11A, but it was confirmed that the phase separation occurred slightly on the first side surface (85°) as shown in FIGS. 10B and 11B and on the second side surface (80°) as illustrated in FIGS. 10C and 11C.

These results may be confirmed together through FIGS. 14A to 14C. In FIGS. 14A to 14C, irradiance was measured using the display device with “LG” written in the center as a reference point 0. Looking at FIG. 14A, it may be seen that the phase separation occurred only in Comparative Embodiment at the front surface (90°) and thus a peak rose on both sides. Referring to FIGS. 14B and 14C, it may be seen that the phase separation also occurred in the display device according to Embodiments 1-1 and 1-2 on the first side surface (85°) and the second side surface (80°) and thus the peak rose on both sides. However, it may be seen that the height of the peak is lower than that of Comparative Embodiment, and the degree is weak.

Looking at the FOS image of the front surface (90°), the first side surface (85°), and the second side surface (80°) of Comparative Embodiment, Embodiment 2-1, and Embodiment 2-2 with reference to the drawings, in the case of Comparative Embodiment, it may be seen that the phase separation occurred on both the front side surface (90°) as illustrated in FIG. 9A, the first side surface (85°) as illustrated in FIG. 9B, and the second side surface (80°) as illustrated in FIG. 9C.

In the case of Embodiment 2-1 and Embodiment 2-2, it may be seen that the phase separation did not occur at the front surface (90°) as illustrated in FIGS. 12A and 13A. In addition, it was confirmed that the phase separation did not occur on the first side surface (85°) as illustrated in FIG. 12B and FIG. 13B and on the second side surface (80°) as illustrated in FIG. 12C and FIG. 13C.

These results may be confirmed together through FIGS. 15A to 15C. In FIGS. 15A to 15C, irradiance was measured using the display device with “LG” written in the center as a reference point 0. Looking at FIG. 15A, it was confirmed that the phase separation occurred only in Comparative Embodiment at the front surface (90°) and thus the peak rose on both sides. Referring to FIGS. 15B and 15C, only in Comparative Embodiment, the phase separation occurred on the first side surface (85°) and the second side surface (80°), and the peak rose on both sides, and in the display device according to Embodiments 2-1 and 2-2, it was confirmed that the peak according to the phase separation did not rise. That is, when adding the unevenness shape H to the side surface of the plurality of dielectric patterns 283b having the step shape as in Embodiment 2-1 and Embodiment 2-2, it was confirmed that the problem of phase separation caused by the surface reflection in the transmissive mode was further improved.

The exemplary embodiments of the present disclosure can also be described as follows:

According to an aspect of the present disclosure, A light controlling panel, comprising a first electrode, a second electrode disposed on the first electrode to face the first electrode, a dielectric layer including a plurality of dielectric patterns that are provided between the first electrode and the second electrode and disposed between a plurality of grooves, and a plurality of spacers that protrude toward the second electrode from a portion of the plurality of dielectric patterns, and an ink layer disposed in a space between the dielectric layer and the second electrode and containing charged particles, a side surfaces of the plurality of dielectric patterns have a step shape.

The plurality of dielectric patterns may have a trapezoidal shape with a lower surface wider than an upper surface and may include a transparent material.

The plurality of spacers may extend in a first direction, and the plurality of grooves extends in the same direction as the extension direction of the plurality of spacers.

A top surfaces of the plurality of dielectric patterns and the plurality of spacers may have a flat shape.

The side surfaces of the plurality of dielectric patterns having the step shape may have a unevenness shape.

The plurality of dielectric patterns and the plurality of spacers may be integrally disposed.

The first electrode includes a plurality of patterned pattern electrodes spaced apart from each other, and the plurality of pattern electrodes may extend in a second direction intersecting the first direction.

The first electrode and the second electrode may be formed of a transparent conductive material.

A side surfaces of the plurality of grooves may have a step shape.

According to another aspect of the present disclosure, a display device, comprising a transparent display panel including a transmissive area through which external light transmits and a non-transmissive area where a plurality of pixels is disposed, and a light controlling panel disposed below the transparent display panel, the light controlling panel includes a first electrode, a second electrode disposed on the first electrode to face the first electrode, a dielectric layer including a plurality of dielectric patterns that are provided between the first electrode and the second electrode and disposed between a plurality of grooves, and a plurality of spacers that protrude toward the second electrode from a portion of the plurality of dielectric patterns, and an ink layer disposed in a space between the dielectric layer and the second electrode and containing charged particles, and side surfaces of the plurality of dielectric patterns have a step shape.

The plurality of spacers may extend in a first direction, and the plurality of grooves may extend in the same direction as the extension direction of the plurality of spacers.

A top surfaces of the plurality of dielectric patterns and the plurality of spacers may have a flat shape.

The side surfaces of the plurality of dielectric patterns having the step shape may have a unevenness shape.

The plurality of dielectric patterns and the plurality of spacers may be integrally disposed.

When a voltage is applied between the first electrode and the second electrode, the charged particles may be located within the plurality of grooves.

The first electrode includes a plurality of patterned pattern electrodes spaced apart from each other, and the plurality of pattern electrodes may extend in a second direction intersecting the first direction.

When a voltage is applied between the first electrode and the second electrode, the charged particles may be located at intersections of the plurality of pattern electrodes and the plurality of grooves.

The side surfaces of the plurality of grooves have the step shape, and the side surfaces of the plurality of grooves having the step shape may have a unevenness shape.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light controlling panel, comprising:
a first electrode;
a second electrode on the first electrode and facing the first electrode;
a dielectric layer including a plurality of dielectric patterns that are between the first electrode and the second electrode and between a plurality of grooves, and a plurality of spacers that protrude toward the second electrode from a portion of the plurality of dielectric patterns; and
an ink layer in a space between the dielectric layer and the second electrode, the ink layer containing charged particles,
wherein side surfaces of the plurality of dielectric patterns have a step shape.

2. The light controlling panel of claim 1, wherein the plurality of dielectric patterns has a trapezoidal shape with a lower surface that is wider than an upper surface and the plurality of dielectric patterns include a transparent material.

3. The light controlling panel of claim 1, wherein the plurality of spacers extend in a first direction, and the plurality of grooves extend in a same direction as an extension direction of the plurality of spacers.

4. The light controlling panel of claim 1, wherein top surfaces of the plurality of dielectric patterns and the plurality of spacers have a flat shape.

5. The light controlling panel of claim 1, wherein a light blocking pattern is coated on top surfaces of the plurality of spacers.

6. The light controlling panel of claim 1, wherein the side surfaces of the plurality of dielectric patterns having the step shape have an unevenness shape.

7. The light controlling panel of claim 1, wherein the plurality of dielectric patterns and the plurality of spacers are integrally disposed.

8. The light controlling panel of claim 3, wherein the first electrode includes a plurality of patterned pattern electrodes spaced apart from each other, and the plurality of patterned pattern electrodes extend in a second direction intersecting the first direction.

9. The light controlling panel of claim 1, wherein the first electrode and the second electrode include a transparent conductive material.

10. The light controlling panel of claim 1, wherein side surfaces of the plurality of grooves have a step shape.

11. A display device, comprising:
a transparent display panel including a transmissive area through which external light transmits and a non-transmissive area where a plurality of pixels are disposed; and
a light controlling panel below the transparent display panel, wherein the light controlling panel includes:
a first electrode,
a second electrode on the first electrode and faces the first electrode,
a dielectric layer including a plurality of dielectric patterns that are between the first electrode and the second electrode and between a plurality of grooves, and a plurality of spacers that protrude toward the second electrode from a portion of the plurality of dielectric patterns, and
an ink layer in a space between the dielectric layer and the second electrode, the ink layer containing charged particles,
wherein side surfaces of the plurality of dielectric patterns have a step shape.

12. The display device of claim 11, wherein the plurality of spacers extend in a first direction, and the plurality of grooves extends in a same direction as an extension direction of the plurality of spacers.

13. The display device of claim 11, wherein top surfaces of the plurality of dielectric patterns and the plurality of spacers have a flat shape.

14. The display device of claim 11, wherein the side surfaces of the plurality of dielectric patterns having the step shape have an unevenness shape.

15. The display device of claim 11, wherein the plurality of dielectric patterns and the plurality of spacers are integrally disposed.

16. The display device of claim 11, wherein responsive to a voltage being applied between the first electrode and the second electrode, the charged particles are located within the plurality of grooves.

17. The display device of claim 12, wherein the first electrode includes a plurality of patterned pattern electrodes spaced apart from each other, and the plurality of patterned pattern electrodes extend in a second direction that intersects the first direction.

18. The display device of claim 17, wherein responsive to a voltage being applied between the first electrode and the second electrode, the charged particles are located at intersections of the plurality of patterned pattern electrodes and the plurality of grooves.

19. The display device of claim 11, wherein the side surfaces of the plurality of grooves have the step shape, and the side surfaces of the plurality of grooves having the step shape have an unevenness shape.
